(19) United States
(12) Patent Application Publication
(10) Pub. No.: US 2006/0198214 A1
(43) Pub. Date: Sep. 7, 2006

(54) Circuits and methods for controlling timing skew in semiconductor memory devices

(75) Inventors: Du-Yeul Kim, Gyeonggi-do (KR); Sung-Min Seo, Gyeonggi-do (KR); Byung-Hoon Jeong, Gyeonggi-do (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 11/342,955

(22) Filed: Jan. 30, 2006

(30) Foreign Application Priority Data
Jan. 28, 2005 (KR) 10-2005-0007962

(51) Int. Cl. G11C 29/00

(52) U.S. Cl. 365/200

(57) ABSTRACT

A circuit for controlling timing skew in a semiconductor memory device includes a skew control circuit that is configured generate separate skew control signals for each respective one of a plurality of memory banks included in the semiconductor memory device. Related methods are also disclosed.

### CROSS-REFERENCE TO RELATED APPLICATION

This application claims priority to Korean Application No. 10-2005-0007962, filed Jan. 28, 2005 in the Korean Intellectual Property Office, the disclosure of which is hereby incorporated herein by reference.

### FIELD OF THE INVENTION

The present invention relates to semiconductor memory devices, and more particularly, to test circuits for semiconductor memory devices.

### BACKGROUND

A semiconductor memory device generally includes a plurality of memory banks. To satisfy operation of high frequency in the semiconductor memory device, skew among signals per memory bank should be controlled. Particularly, when the number of memory banks is large, the skew among signals per memory bank may become difficult to control. A general test signal may control signals of all memory banks within a semiconductor memory device in the same direction (i.e., delay or advance) with the same value, thus it may be difficult to control only a single internal signal of a particular memory bank. That is, skew among internal signals per bank may be reduced by controlling delay time of an internal signal etc. per memory bank.

FIG. 1 is a block diagram of semiconductor memory device having a test circuit according to the prior art. In FIG. 1 a semiconductor memory device includes a plurality of memory banks, that is, a first memory bank BANK_A 10, a second memory bank BANK_B 20, a third memory bank BANK_C 30, a fourth memory bank BANK_D 40, a fifth memory bank BANK_E 50, a sixth memory bank BANK_F 60, a seventh memory bank BANK_G 70, an eighth memory bank BANK_H 80, a test mode register set signal generator TEST_MRS 100 and a fuse mode register set signal generator FUSE_MRS 200.

A generating method and function of a mode register set signal are well known to those skilled in the art for a Dynamic Random Access Memory (DRAM), thus a detailed description is omitted from this disclosure. Particularly, when the mode register set signal is used for testing, it is sometime referred to as a test mode register set. A fuse mode register set signal functions to add or remove a delay time etc. in an amount corresponding to the related fuse. It may be determined whether a corresponding fuse will be cut or not by an input of another mode register set signal. After packaging the semiconductor memory device, an electric fuse is used generally.

Control signals CON_TMRS and CON_FUSE are output from the test mode register set signal generator TEST_MRS 100 and the fuse mode register set signal generator FUSE_MRS 200, and all banks 10, 20, 30, 40, 50, 60, 70 and 80 are provided with the same delay time or value by the control signals, to control internal signals within the banks. Even if there is skew between internal signals within a bank, the internal signals are provided with the same delay time or direction, thus the skew may not be reduced.

### SUMMARY

Embodiments according to the invention can provide circuits and methods for controlling timing skew in semiconductor memory devices. Pursuant to these embodiments, a test circuit for testing memory bank control signals in a semiconductor memory device has a plurality of memory banks that perform predetermined memory operations in response to the memory bank control signals and a test programmable part that is configured to generate a test signal. A separate skew control circuit is configured to control a skew of memory bank control signals for some of a plurality of memory banks in response to the test signal.

In some embodiments according to the invention, the test programmable part is a test mode register set command. In some embodiments according to the invention, the skew of control signals for one memory bank are controlled among the plurality of memory banks. In some embodiments according to the invention, the skew of control signals for two memory banks are controlled among the plurality of memory banks.

In some embodiments according to the invention, the control signal of the memory bank is a signal associated with a row address signal. In some embodiments according to the invention, the control signal of the memory bank is a signal associated with a column address signal. In some embodiments according to the invention, the semiconductor memory device is a dynamic random access memory.

In some embodiments according to the invention, a semiconductor memory device includes a plurality of memory banks respectively distinguished by bits in an address including a bank test signal generating circuit that is configured to selectively generate respective bank test signals for some memory banks of the plurality of memory banks, to substantially reduce skew for internal signals per bank output from the plurality of memory banks.

In some embodiments according to the invention, a test circuit of a semiconductor memory device has a plurality of memory banks including a test mode register set signal generator that is configured to independently provide a test signal in a unit of one or more banks among the plurality of memory banks in an internal signal skew test mode. A fuse mode register set signal generator is configured to independently supply a control signal for a fuse program in a unit of one or more banks among the plurality of memory banks by a skew result of bank internal signals respectively measured through the test signals, in a fuse program mode for a skew correction.

In some embodiments according to the invention, a circuit for controlling timing skew in a semiconductor memory device includes a skew control circuit that is configured generate separate skew control signals for each respective one of a plurality of memory banks included in the semiconductor memory device.

In some embodiments according to the invention, the skew control circuit is a test MRS skew control circuit configured for operation to testing during fabrication of the semiconductor memory device before packaging of the semiconductor memory device. In some embodiments according to the invention, the skew control circuit is a fuse MRS skew control circuit that is configured to generate the separate skew control signals during operation of the semiconductor memory device after packaging of the semiconductor memory device.

In some embodiments according to the invention, a method for controlling timing skew in a semiconductor memory device is provided by generating separate skew control signals for each respective one of a plurality of memory banks included in the semiconductor memory device.

### BRIEF DESCRIPTION OF THE DRAWINGS

FIG. 1 is a block diagram of a semiconductor memory device having a test circuit according to the prior art.

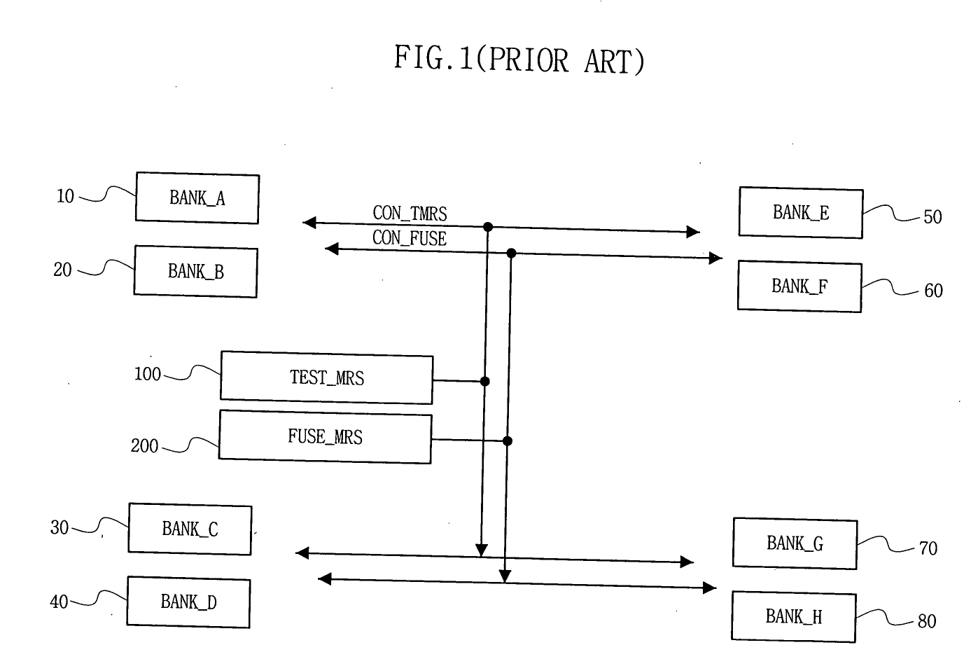

FIG. 2 is a block diagram of semiconductor memory device having a test circuit according to some embodiments of the invention.

### DESCRIPTION OF EMBODIMENTS ACCORDING TO THE INVENTION

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element from another. Thus, a first element discussed below could be termed a second element without departing from the teachings of the present invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

This invention may, however, be embodied in many different forms and should not be construed as being limited to the exemplary embodiments set forth herein; rather, these exemplary embodiments are provided so that this disclosure is thorough and complete, and conveys the concept of the invention to those skilled in the art.

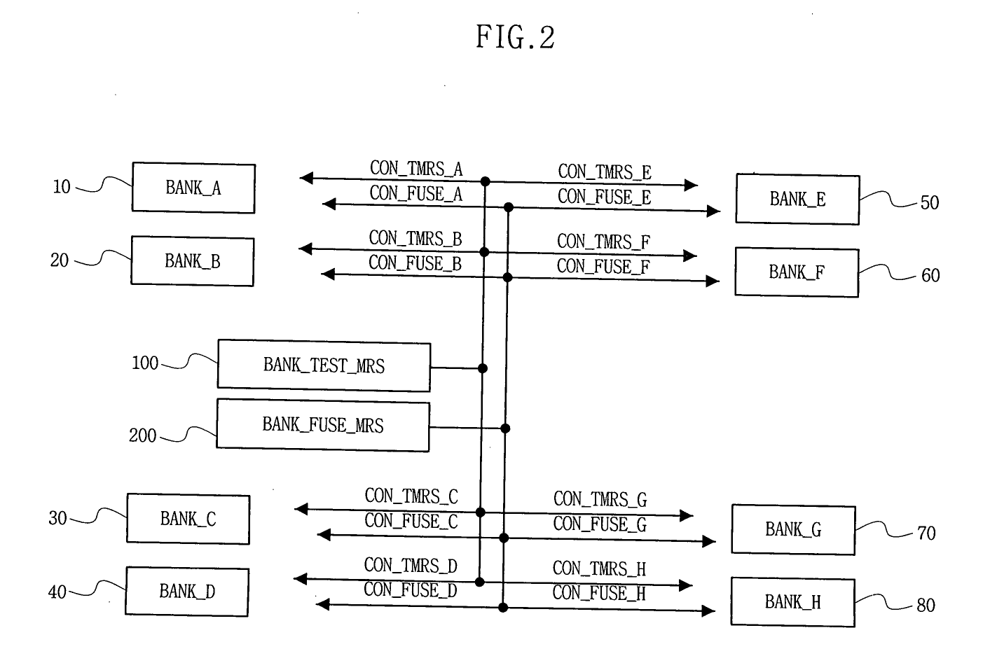

FIG. 2 is a block diagram of a semiconductor memory device having a test circuit according to some embodiments of the invention. Referring to FIG. 2, a semiconductor memory device includes a first memory bank BANK_A 10, a second memory bank BANK_B 20, a third memory bank BANK_C 30, a fourth memory bank BANK_D 40, a fifth memory bank BANK_E 50, a sixth memory bank BANK_F 60, a seventh memory bank BANK_G 70, an eighth memory bank BANK_H 80, a bank test mode register set signal generator BANK_TEST_MRS 300 and a bank fuse mode register set signal generator BANK_FUSE_MRS 400. Accordingly, separate control signals are provided to each bank of memory. More specifically, separate fuse control signals and a separate TMRS control signal are provided to each bank of memory. Therefore, in some embodiments according to the invention, different banks of memory may be provided with different skew control signals so that the skew between banks may be compensated for separately. For example, some banks that are located farther from an address bus than other banks may experience increased skew because of the additional distance. According to some embodiments of the invention, the banks that are farther away may be compensated differently than those located closer.

The bank test mode register set signal generator 300 generates respective bank control signals CON_TMRS_A, CON_TMRS_B, CON_TMRS_C, CON_TMRS_D, CON_TMRS_E, CON_TMRS_F, CON_TMRS_G and CON_TMRS_H.

Respective banks can be divided into a plurality of mats distinguished by some bits of a row address (not shown) or column address (not shown). The mat is a block subdivided from the bank, and can be called a block. The control signals can be subdivided into control signals for a plurality of mats. For example, the control signals can be subdivided into mat control signals CON_TMRS_A_MAT_A and CON_TMRS_A_MAT_B so as to perform a control per mat.

The control signals can perform a control per one bank or per two banks as described above. That is, the semiconductor memory device of the invention can be configured so that control signals can control some memory banks among the plurality of memory banks.

On the basis of the result measured for skews of signals per bank by using control signals generated form the test mode register set signal generator 300, and by cutting a fuse (not shown) through a control signal generated from a fuse mode register set signal generator 400, skews of bank internal signals can be reduced. Beneficially, the fuse is an electric fuse usable after packaging. The function of fuses is known to those skilled in the art, thus a detailed description is omitted from this description. In addition, the mode register set command or signal is a command for determining a CAS latency or burst length mode etc. in a DRAM, in other words, a specific mode determination is valid according to an address value, and this also is known to those skilled in the art, thus a detailed description therefor is omitted from the description.

As described above, according to some embodiments of the invention, a test circuit can reduce skew between signals per bank, therefore allowing higher frequency operation for a semiconductor memory device having a plurality of memory banks.

While the present invention has been particularly shown and described with reference to exemplary embodiments thereof, it will be understood by those skilled in the art that various changes in form and details may be made therein without departing from the spirit and scope of the present invention as defined by the appended claims. For example, a test signal for all banks, and a test signal per bank, are selectively used, and when necessary, an internal signal can be controlled. Accordingly, these and other changes and modifications are seen to be within the true spirit and scope of the invention as defined by the appended claims.

What is claimed:

1. A test circuit for testing memory bank control signals in a semiconductor memory device having a plurality of memory banks that perform predetermined memory operations in response to the memory bank control signals, the test circuit comprising:
a test programmable part configured to generate a test signal; and
a separate skew control circuit configured to control a skew of memory bank control signals for some of a plurality of memory banks in response to the test signal.

2. The circuit of claim 1, wherein the test programmable part comprises a test mode register set command.

3. The circuit of claim 1, wherein the skew of control signals for one memory bank are controlled among the plurality of memory banks.

4. The circuit of claim 1, wherein the skew of control signals for two memory banks are controlled among the plurality of memory banks.

5. The circuit of claim 1, wherein the control signal of the memory bank comprises a signal associated with a row address signal.

6. The circuit of claim 1, wherein the control signal of the memory bank comprises a signal associated with a column address signal.

7. The circuit of claim 1, wherein the semiconductor memory device comprises a dynamic random access memory.

8. A semiconductor memory device including a plurality of memory banks respectively distinguished by bits in an address, the device comprising:
a bank test signal generating circuit configured to selectively generate respective bank test signals for some memory banks of the plurality of memory banks, to substantially reduce skew for internal signals per bank output from the plurality of memory banks.

9. A test circuit of a semiconductor memory device having a plurality of memory banks, the circuit comprising:
a test mode register set signal generator configured to independently provide a test signal in a unit of one or more banks among the plurality of memory banks in an internal signal skew test mode; and
a fuse mode register set signal generator for independently supplying a control signal for a fuse program in a unit of one or more banks among the plurality of memory banks by a skew result of bank internal signals respectively measured through the test signals, in a fuse program mode for a skew correction.

10. A circuit for controlling timing skew in a semiconductor memory device, the circuit comprising:
a skew control circuit configured to generate separate skew control signals for each respective one of a plurality of memory banks included in the semiconductor memory device.

11. A circuit according to claim 10 wherein the skew control circuit comprises a test MRS skew control circuit configured for operation to testing during fabrication of the semiconductor memory device before packaging of the semiconductor memory device.

12. A circuit according to claim 10 wherein the skew control circuit comprises a fuse MRS skew control circuit configured to generate the separate skew control signals during operation of the semiconductor memory device after packaging of the semiconductor memory device.

13. A circuit according to claim 10 wherein the control signals of the memory bank comprises signals associated with a row address signal.

14. A circuit according to claim 10 wherein the control signals of the memory bank comprises a signal associated with a column address signal.

15. A circuit according to claim 10 wherein the semiconductor memory device comprises a dynamic random access memory.

16. A method for controlling timing skew in a semiconductor memory device, the method comprising:
generating separate skew control signals for each respective one of a plurality of memory banks included in the semiconductor memory device.
